(19) United States
(12) Patent Application Publication
(10) Pub. No.: US 2024/0196569 A1
(43) Pub. Date: Jun. 13, 2024

(54) THERMAL ISOLATION FOR MEMORY SYSTEMS

(71) Applicant: Micron Technology, Inc., Boise, ID (US)

(72) Inventors: Suresh Reddy Yarragunta, Bangalore (IN); Deepu Narasimiah Subhash, Bangalore (IN)

(21) Appl. No.: 18/533,024

(22) Filed: Dec. 7, 2023

Related U.S. Application Data
(60) Provisional application No. 63/432,312, filed on Dec. 13, 2022.

(51) Int. Cl. H05K 7/20

(52) U.S. Cl. CPC H05K 7/20509

(57) ABSTRACT

Methods, systems, and devices for thermal isolation for memory systems are described. The enclosed heatsink architectures may impede heat transfer from a first group of components to a second group components. Some examples include a partition (an air gap or other thermally insulating material) between multiple heatsinks. The heatsinks may each have heat transfer elements with various structures. In some examples, a first heatsink may overlap a second heatsink. The overlapping architecture may increase the size of the heatsink corresponding to the first set of components and increase their rate of heat exchange. In some examples, the heatsink architecture may include upper heatsinks and lower heatsinks. The enclosed heatsink architectures may reduce device overheating and time spent in thermal throttling, as well as improve the life expectancy, durability, efficiency, and performance of the memory devices. Increased efficiency in cooling the device may save energy costs.

### CROSS REFERENCE

The present application for patent claims the benefit of U.S. Provisional Patent Application No. 63/432,312 by YARRAGUNTA et al., entitled “THERMAL ISOLATION FOR MEMORY SYSTEMS,” filed Dec. 13, 2022, assigned to the assignee hereof, and expressly incorporated by reference in its entirety herein.

### TECHNICAL FIELD

The following relates to one or more systems for memory, including thermal isolation for memory systems.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports thermal isolation for memory systems in accordance with examples as disclosed herein.

FIG. 2 illustrates an example of a system that supports thermal isolation for memory systems in accordance with examples as disclosed herein.

FIG. 3 illustrates an example of a memory system that supports thermal isolation for memory systems in accordance with examples as disclosed herein.

FIGS. 4A and 4B illustrate examples of memory systems that support thermal isolation for memory systems in accordance with examples as disclosed herein.

FIG. 5 illustrates an example of a memory system that supports thermal isolation for memory systems in accordance with examples as disclosed herein.

FIGS. 6A and 6B illustrate examples of memory systems that support thermal isolation for memory systems in accordance with examples as disclosed herein.

### DETAILED DESCRIPTION

Some memory systems, including those with multiple memory devices, may support various services (e.g., datacenter and automotive) that demand low latency access to data, as well as consume high power to support these services. Some memory systems, such as solid-state drives (SSDs), may have low latency and high data throughput due to high power capabilities for various applications. However, in some cases, these memory systems may have reduced reliability due to temperature limitations. Heatsinks draw heat away from components within a device. However, in current designs, high temperature components, such as a controller, may produce sufficient heat to raise the temperature of the heatsink above the recommended operational temperature of other components, such as memory devices, which may decrease the performance of these components. In some cases, thermal throttling can be used to help decrease the temperature of memory systems, but the technique includes slowing down the performance of the memory system to reduce heat generation. Due to thermal throttling or other conditions, the thermal performance of the memory system may not meet certain requirements of some services. For example, requirements for datacenter cooling may demand relatively high ambient temperatures for higher energy efficiency and to save on cooling costs. In some other cases, such as for datacenters, memory system enclosure casings and outer boundaries of memory systems may have limitations (e.g., in their form factors) that impede thermal improvements.

Various aspects of the present disclosure relate to thermal isolation between components of a device. A heatsink architecture, as described herein, may impede heat transfer from a first group of one or more components (e.g., a controller) to a second group of one or more components (e.g., memory devices) to support thermal isolation between the groups of one or more components. In some examples, to support the thermal isolation between components of the device, the device may be configured with a slit or a barrier in a heatsink of the device. The slit may be an air gap or other thermally insulative material and may reduce heat transfer between groups of components by breaking a direct heat transfer path. As such, the slit or barrier may contribute to thermal isolation between the first group of components and the second group of components.

In some examples, heat transfer elements (e.g., fin structures) may be incorporated into one or more of the heatsinks. Heat transfer elements may constrain the flow regime (e.g., cause free flow in noncritical regions and frictional flow in critical temperature regions). There may be any number of heat transfer elements (e.g., fins) in a heatsink. Different heatsinks may each have a different quantity of heat transfer structures and may have heat transfer structures of varying geometry (e.g., thickness). More heat transfer elements may be included in more critical temperature regions. For example, a heatsink corresponding to an area containing memory devices may include a greater quantity of heat transfer elements (e.g., fins). A heatsink corresponding to an area containing components that have high heat generation (e.g., a controller) may include a lesser quantity of heat transfer elements (e.g., fins).

Additionally or alternatively, a first heatsink corresponding to a first group of one or more components (e.g., a controller) may overlap with a second heatsink corresponding to a second group of one or more components (e.g., memory devices). This may prevent or reduce heat transfer from the first group of one or more components to the second group of one or more components. The overlapping architecture may increase the size of the heatsink corresponding to the first set of components. This may enable a higher rate of heat exchange for the first components, which have a high heat load compared to the second components. The heatsink system may include one or more heatsinks above (e.g., on top of) the components and one or more heatsinks below (e.g., on the bottom of) the components. There may be a plurality of fasteners (e.g., with gaskets) to thermally separate the top and bottom heatsinks.

The enclosed heatsink architecture may increase cooling and improve other thermal characteristics for the device. The thermal profile of the device may be more suited to operating conditions. Improving cooling in devices may reduce overheating. High temperatures may reduce the life expectancy, durability, efficiency, and performance of devices. More efficient cooling and lower temperatures in the device may improve the thermal performance of the device, including endurance, efficiency, and reliability, and decrease the amount of time the device uses thermal throttling. Increased efficiency in cooling the device may result in decreased energy usage. Increased energy efficiency may save energy costs.

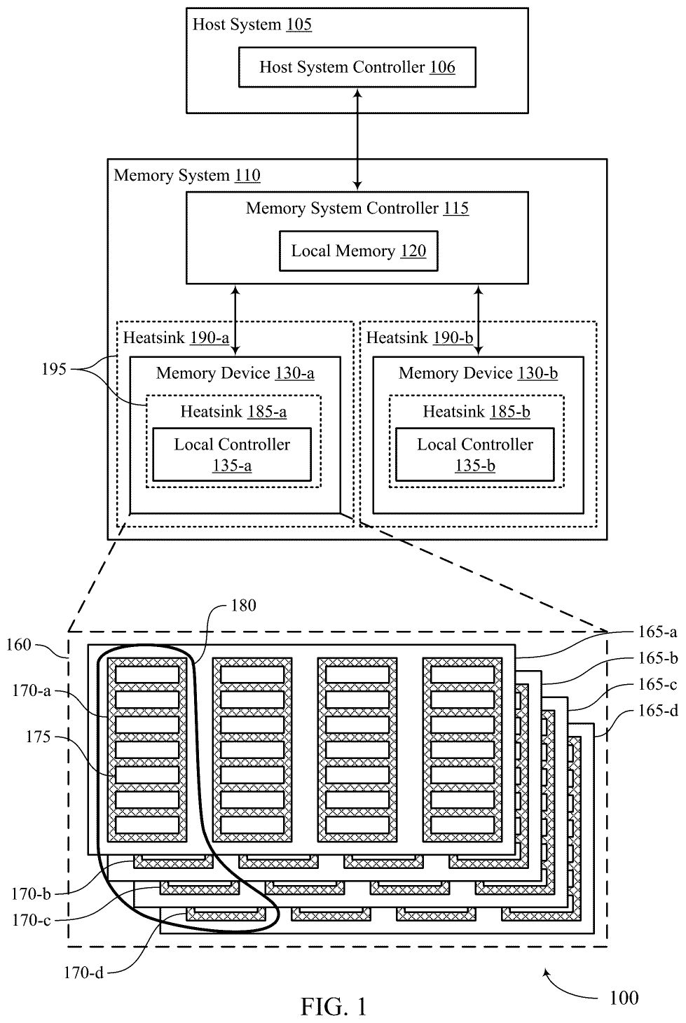

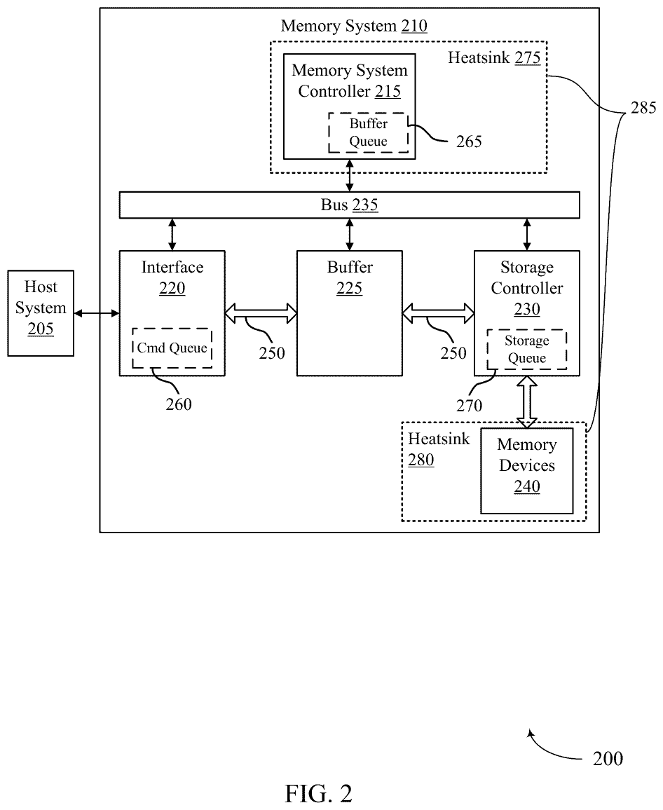

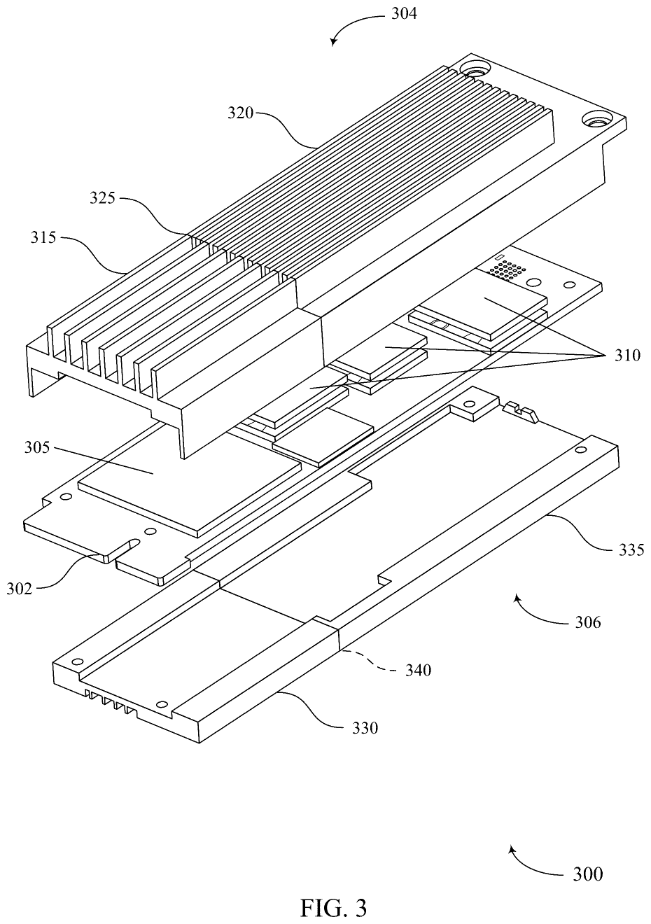

Features of the disclosure are initially described in the context of systems, devices, and circuits with reference to FIGS. 1 through 2. Features of the disclosure are described in the context of a memory device layouts with reference to FIGS. 3 through 6B.

FIG. 1 illustrates an example of a system 100 that supports thermal isolation for memory systems in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IOT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

The system 100 may include any quantity of non-transitory computer readable media that support thermal isolation for memory systems. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

Various aspects of the present disclosure relate to thermal isolation between components of the system 100. For example, various aspects of the present disclosure relate to thermal isolation between components of a host system 105 or a memory system 110. A heatsink architecture, as described herein, may impede heat transfer from a first group of one or more components (e.g., one or more host system controllers 106, memory system controllers 115, and/or local controllers 135) to a second group of one or more components (e.g., one or more memory devices 130, memory dies 160) to support thermal isolation between the groups of one or more components. For example, to support the thermal isolation between components of the memory system 110, the system 100 may be configured with a partition (e.g., a slit or a barrier) located between a first heatsink 185 corresponding to the first group of components (e.g., a local controller 135) and a second heatsink 190 corresponding to the second group of components (e.g., one or more memory devices 130). The partition may contribute to thermal isolation between the first group and second groups of components.

Additionally or alternatively, a first heatsink 185 corresponding to a first group of one or more components (e.g., one or more host system controllers 106, memory system controllers 115, and/or local controllers 135) may overlap with a second heatsink 190 corresponding to a second group of one or more components (e.g., one or more memory devices 130, memory dies 160). The separation between the first heatsink 185 and the second heatsink 190 may prevent or reduce heat transfer from the first group of components to the second group of components. Heatsinks may have various sizes (e.g., varying length, height, and/or width). The first heatsink may have a first length that is different from a second length of the second heatsink. For example, in an overlapping architecture, the first heatsink may be longer than the second heatsink, which may result in the first heatsink having a greater size than the second heatsink. The greater size of the first heatsink may enable a higher rate of heat exchange (when compared to the second, smaller heatsink) for the first components (e.g., a local controller 135), which may have a high heat load compared to the second components (e.g., memory devices 130). The heatsink system 195 may include one or more heatsinks above (e.g., on top of) the components and one or more heatsinks below (e.g., on the bottom of) the components.

FIG. 2 illustrates an example of a system 200 that supports thermal isolation for memory systems in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more memory devices 240 to store data transferred between the memory system 210 and the host system 205 (e.g., in response to receiving access commands from the host system 205). The memory devices 240 may include one or more memory devices as described with reference to FIG. 1. For example, the memory devices 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM, among other examples.

The memory system 210 may include a storage controller 230 for controlling the passing of data directly to and from the memory devices 240 (e.g., for storing data, for retrieving data, for determining memory locations in which to store data and from which to retrieve data). The storage controller 230 may communicate with memory devices 240 directly or via a bus (not shown), which may include using a protocol specific to each type of memory device 240. In some cases, a single storage controller 230 may be used to control multiple memory devices 240 of the same or different types. In some cases, the memory system 210 may include multiple storage controllers 230 (e.g., a different storage controller 230 for each type of memory device 240). In some cases, a storage controller 230 may implement aspects of a local controller 135 as described with reference to FIG. 1.

The memory system 210 may include an interface 220 for communication with the host system 205, and a buffer 225 for temporary storage of data being transferred between the host system 205 and the memory devices 240. The interface 220, buffer 225, and storage controller 230 may support translating data between the host system 205 and the memory devices 240 (e.g., as shown by a data path 250), and may be collectively referred to as data path components.

Using the buffer 225 to temporarily store data during transfers may allow data to be buffered while commands are being processed, which may reduce latency between commands and may support arbitrary data sizes associated with commands. This may also allow bursts of commands to be handled, and the buffered data may be stored, or transmitted, or both (e.g., after a burst has stopped). The buffer 225 may include relatively fast memory (e.g., some types of volatile memory, such as SRAM or DRAM), or hardware accelerators, or both to allow fast storage and retrieval of data to and from the buffer 225. The buffer 225 may include data path switching components for bi-directional data transfer between the buffer 225 and other components.

A temporary storage of data within a buffer 225 may refer to the storage of data in the buffer 225 during the execution of access commands. For example, after completion of an access command, the associated data may no longer be maintained in the buffer 225 (e.g., may be overwritten with data for additional access commands). In some examples, the buffer 225 may be a non-cache buffer. For example, data may not be read directly from the buffer 225 by the host system 205. In some examples, read commands may be added to a queue without an operation to match the address to addresses already in the buffer 225 (e.g., without a cache address match or lookup operation).

The memory system 210 also may include a memory system controller 215 for executing the commands received from the host system 205, which may include controlling the data path components for the moving of the data. The memory system controller 215 may be an example of the memory system controller 115 as described with reference to FIG. 1. A bus 235 may be used to communicate between the system components.

In some cases, one or more queues (e.g., a command queue 260, a buffer queue 265, a storage queue 270) may be used to control the processing of access commands and the movement of corresponding data. This may be beneficial, for example, if more than one access command from the host system 205 is processed concurrently by the memory system 210. The command queue 260, buffer queue 265, and storage queue 270 are depicted at the interface 220, memory system controller 215, and storage controller 230, respectively, as examples of a possible implementation. However, queues, if implemented, may be positioned anywhere within the memory system 210.

Data transferred between the host system 205 and the memory devices 240 may be conveyed along a different path in the memory system 210 than non-data information (e.g., commands, status information). For example, the system components in the memory system 210 may communicate with each other using a bus 235, while the data may use the data path 250 through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220 (e.g., according to a protocol, such as a UFS protocol or an eMMC protocol). Thus, the interface 220 may be considered a front end of the memory system 210. After receipt of each access command, the interface 220 may communicate the command to the memory system controller 215 (e.g., via the bus 235). In some cases, each command may be added to a command queue 260 by the interface 220 to communicate the command to the memory system controller 215.

The memory system controller 215 may determine that an access command has been received based on the communication from the interface 220. In some cases, the memory system controller 215 may determine the access command has been received by retrieving the command from the command queue 260. The command may be removed from the command queue 260 after it has been retrieved (e.g., by the memory system controller 215). In some cases, the memory system controller 215 may cause the interface 220 (e.g., via the bus 235) to remove the command from the command queue 260.

After a determination that an access command has been received, the memory system controller 215 may execute the access command. For a read command, this may include obtaining data from one or more memory devices 240 and transmitting the data to the host system 205. For a write command, this may include receiving data from the host system 205 and moving the data to one or more memory devices 240. In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the write command.

In some cases, a buffer queue 265 may be used to control a flow of commands associated with data stored in the buffer 225, including write commands. The buffer queue 265 may include the access commands associated with data currently stored in the buffer 225. In some cases, the commands in the command queue 260 may be moved to the buffer queue 265 by the memory system controller 215 and may remain in the buffer queue 265 while the associated data is stored in the buffer 225. In some cases, each command in the buffer queue 265 may be associated with an address at the buffer 225. For example, pointers may be maintained that indicate where in the buffer 225 the data associated with each command is stored. Using the buffer queue 265, multiple access commands may be received sequentially from the host system 205 and at least portions of the access commands may be processed concurrently.

If the buffer 225 has sufficient space to store the write data, the memory system controller 215 may cause the interface 220 to transmit an indication of availability to the host system 205 (e.g., a “ready to transfer” indication), which may be performed in accordance with a protocol (e.g., a UFS protocol, an eMMC protocol). As the interface 220 receives the data associated with the write command from the host system 205, the interface 220 may transfer the data to the buffer 225 for temporary storage using the data path 250. In some cases, the interface 220 may obtain (e.g., from the buffer 225, from the buffer queue 265) the location within the buffer 225 to store the data. The interface 220 may indicate to the memory system controller 215 (e.g., via the bus 235) if the data transfer to the buffer 225 has been completed.

After the write data has been stored in the buffer 225 by the interface 220, the data may be transferred out of the buffer 225 and stored in a memory device 240, which may involve operations of the storage controller 230. For example, the memory system controller 215 may cause the storage controller 230 to retrieve the data from the buffer 225 using the data path 250 and transfer the data to a memory device 240. The storage controller 230 may be considered a back end of the memory system 210. The storage controller 230 may indicate to the memory system controller 215 (e.g., via the bus 235) that the data transfer to one or more memory devices 240 has been completed.

In some cases, a storage queue 270 may support a transfer of write data. For example, the memory system controller 215 may push (e.g., via the bus 235) write commands from the buffer queue 265 to the storage queue 270 for processing. The storage queue 270 may include entries for each access command. In some examples, the storage queue 270 may additionally include a buffer pointer (e.g., an address) that may indicate where in the buffer 225 the data associated with the command is stored and a storage pointer (e.g., an address) that may indicate the location in the memory devices 240 associated with the data. In some cases, the storage controller 230 may obtain (e.g., from the buffer 225, from the buffer queue 265, from the storage queue 270) the location within the buffer 225 from which to obtain the data. The storage controller 230 may manage the locations within the memory devices 240 to store the data (e.g., performing wear-leveling, performing garbage collection). The entries may be added to the storage queue 270 (e.g., by the memory system controller 215). The entries may be removed from the storage queue 270 (e.g., by the storage controller 230, by the memory system controller 215) after completion of the transfer of the data.

To process a read command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the read command.

In some cases, the buffer queue 265 may support buffer storage of data associated with read commands in a similar manner as discussed with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215 (e.g., via the bus 235) when the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain (e.g., from the buffer 225, from the storage queue 270) the location within one or more memory devices 240 from which to retrieve the data. In some cases, the storage controller 230 may obtain (e.g., from the buffer queue 265) the location within the buffer 225 to store the data. In some cases, the storage controller 230 may obtain (e.g., from the storage queue 270) the location within the buffer 225 to store the data. In some cases, the memory system controller 215 may move the command processed by the storage queue 270 back to the command queue 260.

Once the data has been stored in the buffer 225 by the storage controller 230, the data may be transferred from the buffer 225 and sent to the host system 205. For example, the memory system controller 215 may cause the interface 220 to retrieve the data from the buffer 225 using the data path 250 and transmit the data to the host system 205 (e.g., according to a protocol, such as a UFS protocol or an eMMC protocol). For example, the interface 220 may process the command from the command queue 260 and may indicate to the memory system controller 215 (e.g., via the bus 235) that the data transmission to the host system 205 has been completed.

The memory system controller 215 may execute received commands according to an order (e.g., a first-in-first-out order, according to the order of the command queue 260). For each command, the memory system controller 215 may cause data corresponding to the command to be moved into and out of the buffer 225, as discussed herein. As the data is moved into and stored within the buffer 225, the command may remain in the buffer queue 265. A command may be removed from the buffer queue 265 (e.g., by the memory system controller 215) if the processing of the command has been completed (e.g., if data corresponding to the access command has been transferred out of the buffer 225). If a command is removed from the buffer queue 265, the address previously storing the data associated with that command may be available to store data associated with a new command.

In some examples, the memory system controller 215 may be configured for operations associated with one or more memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. For example, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the described operations in conjunction with or instead of the memory system controller 215. In some cases, the memory system controller 215 may perform the functions of the storage controller 230 and the storage controller 230 may be omitted.

Various aspects of the present disclosure relate to thermal isolation between components of the system 200. For example, various aspects of the present disclosure relate to thermal isolation between components of a host system 205 or a memory system 210. A heatsink architecture, as described herein, may impede heat transfer from a first group of one or more components (e.g., a memory system controller 215, a storage controller 230, or a local controller (not shown) in a memory device 240) to a second group of one or more components (e.g., one or more memory devices 240) to support thermal isolation between the groups of components. In some examples, to support the thermal isolation between components of the memory system 210, the memory system 210 may be configured with a partition (e.g., a slit or a barrier) located between a first heatsink 275 corresponding to the first group of components (e.g., a memory system controller 215 or a storage controller 230, or a local controller for the memory device 240) and a second heatsink 280 corresponding to the second group of components (e.g., one or more memory devices 240). The slit may be an air gap or other thermally insulative material and may reduce heat transfer between groups of components by breaking a direct heat transfer path. As such, the slit or barrier may contribute to thermal isolation between the first group of components (e.g., a memory system controller 215 or a storage controller 230, or a local controller for the memory device 240) and the second group of components (e.g., one or more memory devices 240).

Additionally or alternatively, a first heatsink 275 corresponding to a first group of one or more components (e.g., a memory system controller 215 or a storage controller 230, or a local controller for the memory device 240) may overlap with a second heatsink 280 corresponding to a second group of one or more components (e.g., one or more memory devices 240). This may prevent or reduce heat transfer from the first group of components to the second group of components. The separation between the first heatsink 275 and the second heatsink 280 may prevent or reduce heat transfer from the first group of components to the second group of components. Heatsinks may have various sizes (e.g., varying length, height, and/or width). The first heatsink 275 may have a first length that is different from a second length of the second heatsink 280. For example, in an overlapping architecture, the first heatsink 275 may be longer than the second heatsink 280, which may result in the first heatsink 275 having a greater size than the second heatsink 280. The greater size of the first heatsink 275 may enable a higher rate of heat exchange (when compared to the second heatsink 280 (e.g., the smaller heatsink)) for the first components (e.g., a memory system controller 215 or a storage controller 230, or a local controller for the memory device 240), which may have a high heat load compared to the second components (e.g., memory devices 240). The heatsink system 285 may include one or more heatsinks relative to the components (e.g., the memory system controller 215, the storage controller 230, or the local controller (not shown) in the memory device 240) and one or more heatsinks below (e.g., on the bottom of) the components.

FIG. 3 illustrates an example of a memory system 300 (e.g., a solid-state drive) that supports thermal isolation for memory systems in accordance with examples as disclosed herein. The memory system 300 may include a printed circuit board 302 that may include a circuit region and a connector region. For example, the memory system 300 may include the printed circuit board 302 that includes a controller 305 mounted on the circuit region of the printed circuit board 302. The memory system 300 may include a plurality of memory devices 310 (e.g., NAND memory devices) mounted on the printed circuit board 302 within the circuit region that are electrically coupled with the controller 305. The memory system 300 may also include an upper heat transfer assembly 304 and a medium (e.g., a medium with high thermal conductivity such as a gel or air) between the upper heat transfer assembly 304 and the printed circuit board 302.

The memory system 300 may conform to a form factor that may have a defined mechanical enclosure. The enclosure may include regions that are able to support heatsinks and other regions that are not able to support heatsinks. The upper heat transfer assembly 304 may be configured to extend over the circuit region of the printed circuit board 302. The upper heat transfer assembly 304 may include a first heatsink 315, a second heatsink 320, and a partition 325 between the first heatsink 315 and the second heatsink 320. The 2D top view of the upper heat transfer assembly 304 may generally be the shape of a simple rectangle. The first heatsink 315 may include a first set of heat transfer elements (e.g., fins) and may be thermally coupled with the controller 305, the printed circuit board 302, power management integrated circuit devices, application specified integrated circuit, or a combination thereof. The second heatsink 320 may include a second set of heat transfer elements (e.g., fins) and may be thermally coupled with the plurality of memory devices 310. The partition 325 may be configured to provide thermal isolation between the first heatsink 315 and the second heatsink 320.

The partition 325 may be a physical split between the first heatsink 315 and the second heatsink 320. The first heatsink 315 and the second heatsink 320 may be adjacent to the partition 325. The partition 325 may be a thermally insulative material (e.g., a small air gap, foam, rubber) and may be configured to decrease heat transfer between the first heatsink 315 and the second heatsink 320. In other words, the partition 325 may create two thermal islands (e.g., one island including the controller 305 and another island including the memory devices 310) by decreasing convection heat transfer between them. The partition may, for example, have a thickness (distance between the first heatsink 315 and the second heatsink 320) that is less than 5%, 2%, or 1% of the length of the upper heat transfer assembly 304. As another example, the partition may have a thickness that is less than 5%, 2%, or 1% of the length of the printed circuit board 302. The partition may also have a fixed thickness, such as 1 millimeter.

Each heatsink (e.g., the first heatsink 315 and the second heatsink 320) may conform to an area of a form factor that is provided for the heatsinks in the memory system 300. Each heatsink may fit within a similar envelope of the memory system, may have coextensive sides, or may both have the same length for one dimension. The heatsinks may be arranged such that the edge of one heatsink is aligned with the edge of the other heatsink. The edges of the two heatsinks lining the partition may have the same length. The first heatsink 315 and the second heatsink 320 may have heat transfer elements (e.g., fins) that are different designs or sizes, or both. The first heatsink 315 may have a lower quantity of heat transfer elements (e.g., a coarse fin stack) compared to the second heatsink 320. The lower quantity of heat transfer elements for the first heatsink 315 may decrease the rate of heat exchange compared to the second heatsink 320. The second heatsink 320 may have a higher quantity of heat transfer elements (e.g., a fine fin stack) compared to the first heatsink 315. The higher quantity of heat transfer elements for the second heatsink 320 may increase the rate of heat exchange compared to the first heatsink 315.

Each set of heat transfer elements (e.g., fins) may have various geometries (e.g., height, length, width, etc.). A height of the first set of heat transfer elements (e.g., fins) may be less than a length of the first set of heat transfer elements. A height of the second set of heat transfer elements (e.g., fins) may be less than a length of the second set of heat transfer elements. The first set of heat transfer elements (e.g., fins) on the first heatsink 315 and the second set of heat transfer elements (e.g., fins) on a first heatsink 315 may extend in a first direction. The partition 325 may extend in a second direction perpendicular to the first direction. In some examples, the heat transfer elements may be aligned or staggered. The heat transfer element architecture may improve fluid flow and thermal performance. The heat transfer element architecture may create free flow in noncritical regions (e.g., the region of the first heatsink 315 corresponding to controller 305) and frictional flow in critical temperature regions (e.g., the region of the second heatsink 320 corresponding to memory devices 310). The heat transfer elements (e.g., fins) may minimize the pressure drop from the memory devices 310 to the controller 305. The low pressure drop may lead to more air flow through the heat transfer elements of the second heatsink 320 and more heat exchange between the memory devices 310 and the air.

In some examples, the memory system 300 may also include a lower heat transfer assembly 306 that may or may not be thermally coupled with the upper heat transfer assembly 304. The upper heat transfer assembly 304 and the lower heat transfer assembly 306 may enclose the controller 305 and the plurality of memory devices 310. In other words, the heat transfer assembly (including the upper heat transfer assembly 304 and/or the lower heat transfer assembly 306) may include a portion in the same plane as the printed circuit board 302 that is larger than the printed circuit board 302. The heat transfer assembly may include portions that extend in a direction orthogonal to the plane of the printed circuit board 302 that may cover the sides of the printed circuit board 302. The heat transfer assembly may, for example, completely enclose the printed circuit board 302, may cover four sides of the 3D memory system 300 that has a general shape of a rectangular prism, or may surround 95% of the printed circuit board 302. In some examples, the lower heat transfer assembly 306 may include a third heatsink 330 and a fourth heatsink 335. The third heatsink 330 and the first heatsink 315 may enclose the controller 305. The fourth heatsink 335 and the second heatsink 320 may enclose the plurality of memory devices 310. The third heatsink 330 and the fourth heatsink 335 may be separated by a partition 340 similar to the partition 325 of the upper heat transfer assembly 304.

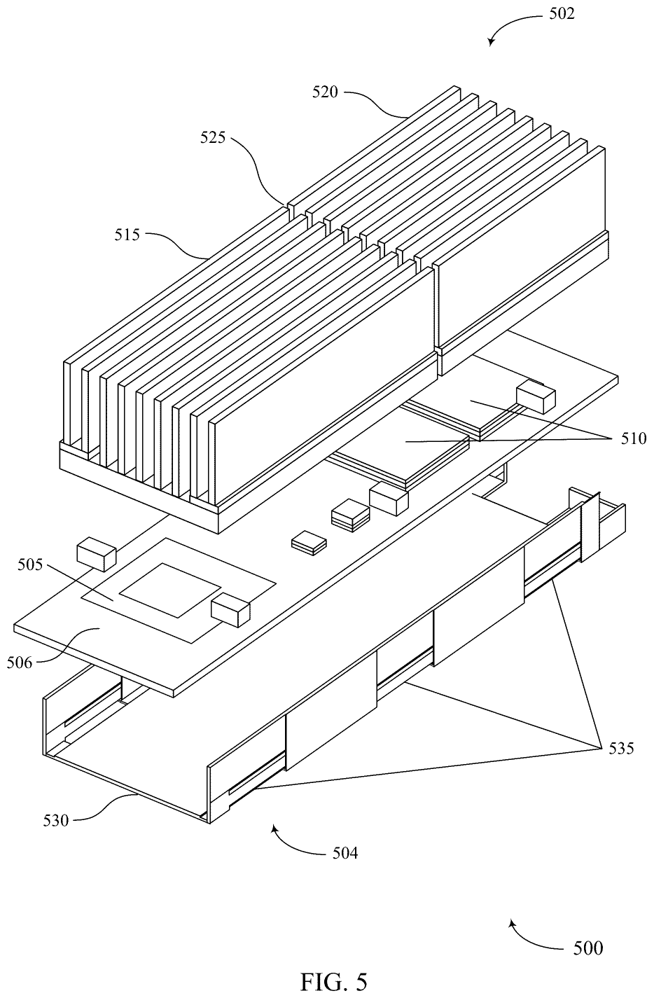

In other examples, the lower heat transfer assembly 306 may include a single heatsink. That is, there may be no partition 340 and the third heatsink 330 and the fourth heatsink 335 may constitute a single heatsink. This example may be further described in FIG. 5.

The heat transfer assembly (e.g., the upper heat transfer assembly 304, the lower heat transfer assembly, or both) may be made of one or more thermally conductive materials (e.g., metal such as Steel, Copper, Magnesium, or Aluminum alloys) and may be fabricated by a variety of processes (e.g., machining, pressure diecasting, additive manufacturing). The heat transfer assembly may have an anodized finish (e.g., which may be black or another color).

The partition 325 and/or the partition 340 may improve thermal isolation between the controller 305 and the memory devices 310. The thermal isolation may improve the performance (e.g., efficiency) of the memory system 300 by allowing each component to operate within the recommended operating temperatures for those components.

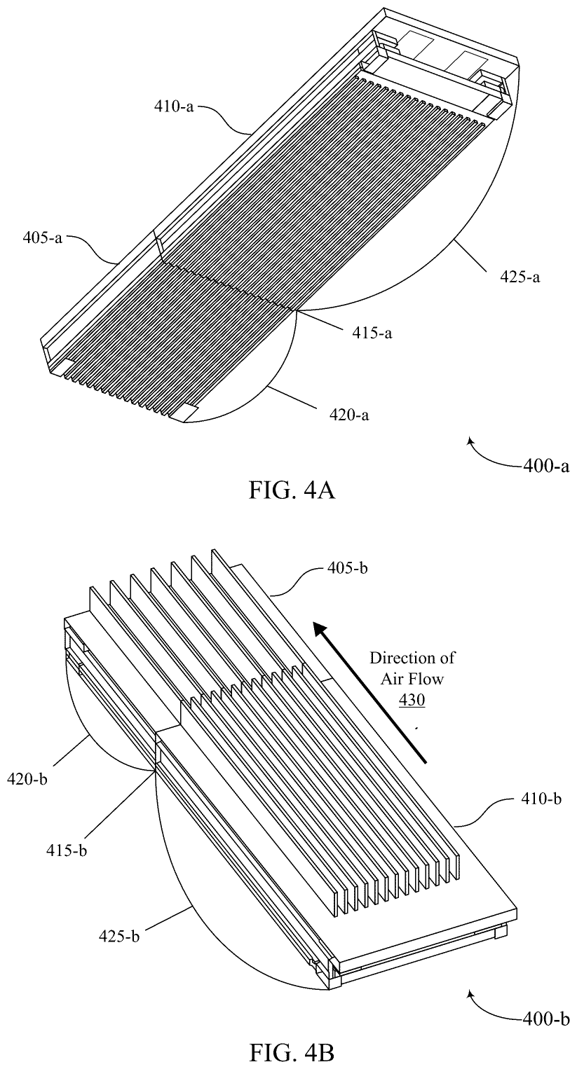

FIG. 4A illustrates an example of a memory system 400-a that supports thermal isolation for memory systems in accordance with examples as disclosed herein. The memory system 400-a may include a first lower heatsink 405-a, a second lower heatsink 410-a, and a partition 415-a between the first lower heatsink 405-a and the second lower heatsink 410-a. The components of FIG. 4A and FIG. 4B may correspond to components described in FIG. 1. The memory system 400-a may include a first temperature signature 420-a corresponding to the temperature of the first lower heatsink 405-a and a second temperature signature 425-a corresponding to the temperature of the second lower heatsink 410-a. The first temperature signature 420-a may be the same or a higher temperature than the second temperature signature 425-a.

FIG. 4B illustrates an example of a memory system 400-b that supports thermal isolation for memory systems in accordance with examples as disclosed herein. The memory system 400-b may include a first upper heatsink 405-b, a second upper heatsink 410-b, and a partition 415-b between the first upper heatsink 405-b and the second upper heatsink 410-b. The components of FIG. 4A and FIG. 4B may correspond to components described in FIG. 1. The memory system 400-b may include a third temperature signature 420-b corresponding to the temperature of the first upper heatsink 405-b and a fourth temperature signature 425-b corresponding to the temperature of the second upper heatsink 410-b. The third temperature signature 420-b may be the same or a higher temperature than the fourth temperature signature 425-b.

The first upper heatsink 405-b may be thermally coupled with the first lower heatsink 405-a. The second upper heatsink 410-b may be thermally coupled with the second lower heatsink 410-a. The first temperature signature 420-a and the third temperature signature 420-b may be similar. The second temperature signature 425-a and the fourth temperature signature 425-b may be similar. The memory system 400-b may include a direction of air flow 430 that is parallel to the plane of the heat transfer assembly. The air may flow from the direction of the second upper heatsink 410-b toward the direction of the first upper heatsink 405-b. The air flow may increase the rate of heat dispersal from the first upper heatsink 405-b and the second upper heatsink 410-b to the air.

FIG. 5 illustrates an example of a memory system 500 that supports thermal isolation for memory systems in accordance with examples as disclosed herein. The memory system 500 may include an upper heat transfer assembly 502 and a lower heat transfer assembly 504. The upper heat transfer assembly 502 may include a first heatsink 515 that is thermally coupled with a controller 505, a second heatsink 520 that is thermally coupled with memory devices 510 (e.g., NAND devices), and a partition 525 (e.g., a small air gap) that may physically separate the first heatsink 515 and the second heatsink 520. The lower heat transfer assembly 504 may include a lower heatsink 530. The components of FIG. 5 may correspond to components described in FIG. 1.

The lower heatsink 530 may correspond to the memory devices 510 of the secondary side of a printed circuit board 506. The lower heatsink 530 may include fasteners 535 (e.g., with gaskets) to connect the lower heatsink 530 to the first heatsink 315 and the second heatsink 320. The fasteners may provide thermal insulation between the heatsinks and impede heat transfer between the upper heat transfer assembly 502 and the lower heat transfer assembly 504.

The partition 525 and/or the fasteners 535 may impede heat transfer between the controller 505 corresponding to the first heatsink 515, and the memory devices 510 corresponding to the second heatsink 520. The thermal isolation may improve the performance (e.g., efficiency) of the memory system 500 by allowing each component to operate within the recommended operating temperatures for those components.

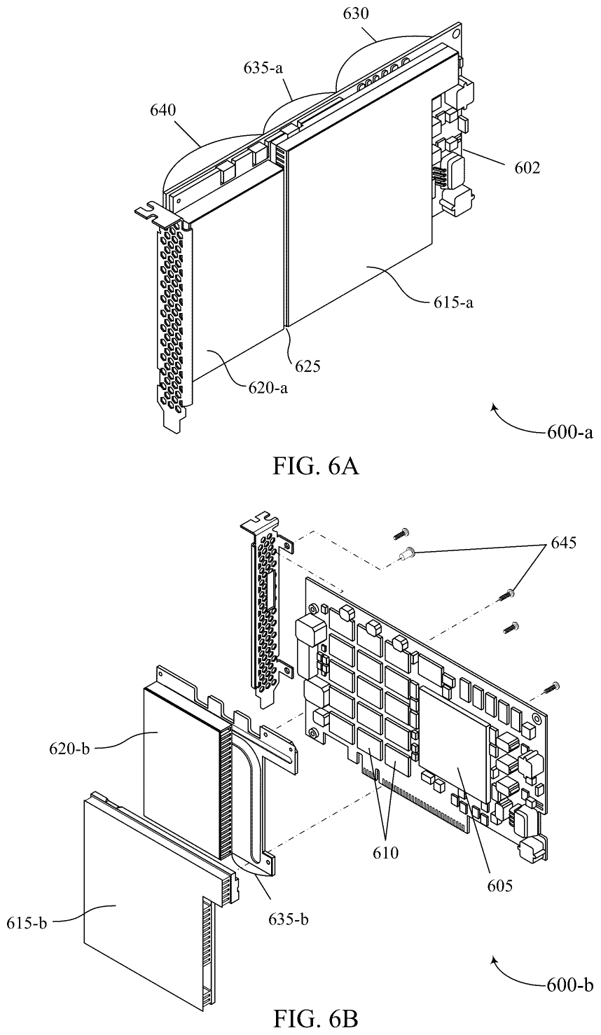

FIG. 6A illustrates an example of a memory system 600-a that supports thermal isolation for memory systems in accordance with examples as disclosed herein. The memory system 600-a may include a printed circuit board 602, a memory device mounted to the printed circuit board 602, a controller mounted to the printed circuit board 602 and electrically coupled with the memory device, and a heat transfer assembly. The controller and the memory devices of the memory system 600-a may correspond to the controller 605 and the memory devices 610 of the memory system 600-b. The heat transfer assembly may include a first heatsink 615-a, a second heatsink 620-a, and a partition 625 between the first heatsink 615-a and the second heatsink 620-a.

The first heatsink 615-a may include a thermally conductive component extending over a first area 630 of the printed circuit board 602 (e.g., over an area corresponding to the controller). The first heatsink 615-a may also include a first thermal transfer component extending over a second area 635-a of the printed circuit board 602.

The memory system 600-a may also include a second heatsink 620-a including a second thermal transfer component extending over a third area 640 of the printed circuit board 602 (e.g., over an area corresponding to the memory devices such as NAND devices, and/or media devices). The third area 640 may partially overlap along a plane of the printed circuit board 602 with the first area 630. The first area 630 may be smaller than the second area 635-a. In some cases, the third area 640 may be smaller than both the first area 630 and the second area 635-a.

The partition 625 between the first heatsink 615-a and the second heatsink 620-a may be an air gap or a thermal insulation layer and may be configured to provide thermal isolation between the first heatsink 615-a and the second heatsink 620-a. The partition 625 may extend in a direction orthogonal to the plane of the heat transfer assembly.

The first heat transfer assembly (e.g., the first heatsink 615-a, the second heatsink 620-a, or both) may be made of one or more thermally conductive materials (e.g., metal such as Steel, Copper, Magnesium, or Aluminum alloys) and may be fabricated by a variety of processes (e.g., machining, pressure diecasting, additive manufacturing). The heat transfer assembly may have an anodized finish (e.g., which may be black or another color).

The partition 625 may impede heat flow from the controller to other devices (e.g., media devices). The partition 625 may act as a thermal barrier between the controller and other devices (e.g., media devices). The second area 635-a with the first area 630 of the first heatsink 615-a may provide a higher rate of heat exchange for the printed circuit board 602 corresponding to the controller with the air than the rate of heat exchange of the first area 630) alone. In other words, the overlapping heatsink architecture may provide a higher rate of heat exchange for the portion of the printed circuit board 602 that has a high heat load and low surface area (e.g., the controller) compared to other portions of the printed circuit board 602 (e.g., memory devices). Thermal isolation between the first heatsink 615-a and the second heatsink 620-a may improve the performance (e.g., improved efficiency, decreased time spent thermal throttling, lengthened NAND life expectancy, improved NAND reliability and/or durability) of the memory system 600-a by allowing each component (e.g., a controller, memory devices, NAND devices, media devices) to operate within the recommended operating temperatures for those components (e.g., a reduced operating temperature for NAND devices).

FIG. 6B illustrates an example of a memory system 600-b that supports thermal isolation for memory systems in accordance with examples as disclosed herein. The memory system 600-b may be an expanded view of the memory system 600-a and may include a controller 605, memory devices 610, first heatsink 615-b covering a first area corresponding to the controller 605 and a second area 635-b, a second heatsink 620-b covering a third area corresponding to memory devices 610. The memory system 600-b may also include fasteners 645 that fasten the printed circuit board to the first heatsink 615-b and/or the second heatsink 620-b. The first heatsink 615-b may overlap a portion (e.g., the second area 635-b) of the second heatsink 620-b without being thermally coupled to the second heatsink 620-b, preventing heat transfer from one heatsink to the other.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 1: An apparatus, including: a printed circuit board including a circuit region and a connector region: a controller mounted on the printed circuit board within the circuit region: a plurality of memory devices mounted on the printed circuit board within the circuit region and electrically coupled with the controller: and an upper heat transfer assembly that is configured to extend over the circuit region of the printed circuit board, the upper heat transfer assembly including: a first heatsink including a first set of heat transfer elements, the first heatsink thermally coupled with the controller: a second heatsink including a second set of heat transfer elements, the second heatsink thermally coupled with the plurality of memory devices: and a partition between the first heatsink and the second heatsink configured to provide thermal isolation between the first heatsink and the second heatsink.

Aspect 2: The apparatus of aspect 1, where the first set of heat transfer elements includes a first quantity of heat transfer elements and the second set of heat transfer elements includes a second quantity of heat transfer elements, and the first quantity of heat transfer elements is less than or equal to the second quantity of heat transfer elements.

Aspect 3: The apparatus of any of aspects 1 through 2, where the first heatsink and the second heatsink are positioned adjacent to the partition.

Aspect 4: The apparatus of any of aspects 1 through 3, where the first set of heat transfer elements and the second set of heat transfer elements extend in a first direction.

Aspect 5: The apparatus of aspect 4, where the partition extends in a second direction perpendicular to the first direction.

Aspect 6: The apparatus of any of aspects 1 through 5, where the partition includes an air gap between the first heatsink and the second heatsink.

Aspect 7: The apparatus of any of aspects 1 through 6, further including: a lower heat transfer assembly coupled with the upper heat transfer assembly, where the controller and the plurality of memory devices are enclosed between the upper heat transfer assembly and the lower heat transfer assembly.

Aspect 8: The apparatus of aspect 7, where the lower heat transfer assembly includes: a third heatsink, where the controller is enclosed between the first heatsink and the third heatsink: and a fourth heatsink, where the plurality of memory devices are enclosed between the second heatsink and the fourth heatsink.

Aspect 9: The apparatus of any of aspects 7 through 8, where the lower heat transfer assembly includes a single heat sink, and the lower heat transfer assembly is coupled with the upper heat transfer assembly and are thermally isolating.

Aspect 10: The apparatus of any of aspects 7 through 9, where the upper heat transfer assembly, the lower heat transfer assembly, or both includes an alloy of Aluminum.

Aspect 11: The apparatus of any of aspects 1 through 10, where a height of the first set of heat transfer elements is less than a length of the first set of heat transfer elements, and a height of the second set of heat transfer elements is less than a length of the second set of heat transfer elements.

Aspect 12: The apparatus of any of aspects 1 through 11, where the plurality of memory devices includes a plurality of NAND memory devices.

An apparatus is described. The following provides an overview of aspects of the apparatus as described herein:

Aspect 13: An apparatus, including: a printed circuit board: a memory device mounted to the printed circuit board: a controller mounted to the printed circuit board and electrically coupled with the memory device: and a heat transfer assembly including: a first heatsink including a thermally conductive component extending over a first area of the printed circuit board and a first thermal transfer component extending over a second area of the printed circuit board: a second heatsink including a second thermal transfer component extending over a third area of the printed circuit board, where the third area at least partially overlaps along a plane of the printed circuit board with the first area: and a partition between the first heatsink and the second heatsink configured to provide thermal isolation between the first heatsink and the second heatsink, the partition extending in a direction orthogonal to the plane.

Aspect 14: The apparatus of aspect 13, where the first area is smaller than the second area of the apparatus.

Aspect 15: The apparatus of any of aspects 13 through 14, where the partition includes an air gap between the first heatsink and the second heatsink.

Aspect 16: The apparatus of any of aspects 13 through 15, where the partition includes a thermal insulation layer between the first heatsink and the second heatsink.

Aspect 17: The apparatus of any of aspects 13 through 16, where the first heatsink and the second heatsink include an alloy of Aluminum.

Aspect 18: The apparatus of any of aspects 13 through 17, where the memory device includes a NAND memory device.

An apparatus is described. The following provides an overview of aspects of the apparatus as described herein:
Aspect 19: An apparatus, including: a printed circuit board including a circuit region and a connector region: a controller mounted to the printed circuit board within the circuit region: a set of memory devices mounted to the printed circuit board within the circuit region and electrically coupled with the controller; and an upper heat transfer assembly including: a first heatsink thermally coupled with the controller; a second heatsink thermally coupled with the set of memory devices; a partition between the first heatsink and the second heatsink configured to provide thermal isolation between the first heatsink and the second heatsink: and a lower heat transfer assembly coupled with the upper heat transfer assembly, where the circuit region of the printed circuit board is enclosed between the upper heat transfer assembly and the lower heat transfer assembly.

Aspect 20: The apparatus of aspect 19, where the first heatsink and the second heatsink are adjacent to the partition.

Aspect 21: The apparatus of any of aspects 19 through 20, where the first heatsink and the second heatsink extend in a first direction.

Aspect 22: The apparatus of aspect 21, where the partition extends in a second direction perpendicular to the first direction.

Aspect 23: The apparatus of any of aspects 19 through 22, where the upper heat transfer assembly, the lower heat transfer assembly, or both includes an alloy of Aluminum.

Aspect 24: The apparatus of any of aspects 19 through 23, where the partition includes an air gap between the first heatsink and the second heatsink.

Aspect 25: The apparatus of any of aspects 19 through 24, where the set of memory devices includes a set of not-and (NAND) memory devices.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal: however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow:

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary.” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a printed circuit board comprising a circuit region and a connector region;
a controller mounted on the printed circuit board within the circuit region;
a plurality of memory devices mounted on the printed circuit board within the circuit region and electrically coupled with the controller; and
an upper heat transfer assembly that is configured to extend over the circuit region of the printed circuit board, the upper heat transfer assembly comprising:
a first heatsink including a first set of heat transfer elements, the first heatsink thermally coupled with the controller;
a second heatsink including a second set of heat transfer elements, the second heatsink thermally coupled with the plurality of memory devices; and
a partition between the first heatsink and the second heatsink configured to provide thermal isolation between the first heatsink and the second heatsink.

2. The apparatus of claim 1, wherein the first set of heat transfer elements comprises a first quantity of heat transfer elements and the second set of heat transfer elements comprises a second quantity of heat transfer elements, and the first quantity of heat transfer elements is less than or equal to the second quantity of heat transfer elements.

3. The apparatus of claim 1, wherein the first heatsink and the second heatsink are positioned adjacent to the partition.

4. The apparatus of claim 1, wherein the first set of heat transfer elements and the second set of heat transfer elements extend in a first direction.

5. The apparatus of claim 4, wherein the partition extends in a second direction perpendicular to the first direction.

6. The apparatus of claim 1, wherein the partition comprises an air gap between the first heatsink and the second heatsink.

7. The apparatus of claim 1, further comprising:
a lower heat transfer assembly coupled with the upper heat transfer assembly,
wherein the controller and the plurality of memory devices are enclosed between the upper heat transfer assembly and the lower heat transfer assembly.

8. The apparatus of claim 7, wherein the lower heat transfer assembly comprises:
a third heatsink, wherein the controller is enclosed between the first heatsink and the third heatsink; and
a fourth heatsink, wherein the plurality of memory devices are enclosed between the second heatsink and the fourth heatsink.

9. The apparatus of claim 7, wherein the lower heat transfer assembly comprises a single heat sink, and the lower heat transfer assembly is coupled with the upper heat transfer assembly and are thermally isolating.

10. The apparatus of claim 7, wherein the upper heat transfer assembly, the lower heat transfer assembly, or both comprises an alloy of Aluminum.

11. The apparatus of claim 1, wherein a height of the first set of heat transfer elements is less than a length of the first set of heat transfer elements, and a height of the second set of heat transfer elements is less than a length of the second set of heat transfer elements.

12. The apparatus of claim 1, wherein the plurality of memory devices comprises a plurality of not-and (NAND) memory devices.

13. An apparatus, comprising:
a printed circuit board;
a memory device mounted to the printed circuit board;
a controller mounted to the printed circuit board and electrically coupled with the memory device; and
a heat transfer assembly comprising:
a first heatsink comprising a thermally conductive component extending over a first area of the printed circuit board and a first thermal transfer component extending over a second area of the printed circuit board;
a second heatsink comprising a second thermal transfer component extending over a third area of the printed circuit board, wherein the third area at least partially overlaps along a plane of the printed circuit board with the first area; and
a partition between the first heatsink and the second heatsink configured to provide thermal isolation between the first heatsink and the second heatsink, the partition extending in a direction orthogonal to the plane.

14. The apparatus of claim 13, wherein the first area is smaller than the second area of the apparatus.

15. The apparatus of claim 13, wherein the partition comprises an air gap between the first heatsink and the second heatsink.

16. The apparatus of claim 13, wherein the partition comprises a thermal insulation layer between the first heatsink and the second heatsink.

17. The apparatus of claim 13, wherein the first heatsink and the second heatsink comprise an alloy of Aluminum.

18. The apparatus of claim 13, wherein the memory device comprises a not-and (NAND) memory device.

19. An apparatus, comprising:
a printed circuit board comprising a circuit region and a connector region;
a controller mounted to the printed circuit board within the circuit region;
a set of memory devices mounted to the printed circuit board within the circuit region and electrically coupled with the controller; and
an upper heat transfer assembly comprising:
a first heatsink thermally coupled with the controller;
a second heatsink thermally coupled with the set of memory devices;
a partition between the first heatsink and the second heatsink configured to provide thermal isolation between the first heatsink and the second heatsink; and
a lower heat transfer assembly coupled with the upper heat transfer assembly,
wherein the circuit region of the printed circuit board is enclosed between the upper heat transfer assembly and the lower heat transfer assembly.

20. The apparatus of claim 19, wherein the first heatsink and the second heatsink are adjacent to the partition.
